(19) United States
(12) Patent Application Publication
(10) Pub. No.: US 2016/0112061 A1
(43) Pub. Date: Apr. 21, 2016

(54) NON-RECURSIVE CASCADING REDUCTION

(71) Applicant: International Business Machines Corporation, Armonk, NY (US)

(72) Inventors: Neil E. Bartlett, Toronto (CA); Robert J. Blainey, Newmarket (CA); Barnaby P. Dalton, Mississauga (CA); Dharmendra P. Gupta, Mississauga (CA); Mohammad Fahham A. Khan, Ancaster (CA); Nho Sinh Louis Ly, Richmond Hill (CA); James A. Sedgwick, Toronto (CA); Lior Velichover, Vaughan (CA); Kai-Ting A. Wang, North York (CA)

(21) Appl. No.: 14/519,473

(22) Filed: Oct. 21, 2014

(51) Int. Cl. H03M 7/30

(52) U.S. Cl. CPC H03M 7/30

(57) ABSTRACT

As disclosed herein a method, executed by a computer, for conducting non-recursive cascading reduction includes receiving a collection of floating point values, using a binary representation of an index corresponding to a value being processed to determine a reduction depth for elements on a stack to be accumulated, and according to the reduction depth, iteratively conducting a reduction operation on the current value and one or more values on the stack. In addition to accumulation, the reduction operation may include transforming the value with a corresponding function. The method may also include using a SIMD processing environment to further increase the performance of the method. The method provides results with both high performance and accuracy. A computer system and computer program product corresponding to the method are also disclosed herein.

### STATEMENT REGARDING PRIOR DISCLOSURES BY THE INVENTOR OR A JOINT INVENTOR

The following disclosures are submitted under 35 U.S.C. §102(b)(1)(A):
(1) Barnaby Dalton, Amy Wang, and Bob Blainey, “SIMDizing Pairwise Sums: A summation algorithm balancing accuracy with throughput”, WPMVP '14 Proceedings of the 2014 Workshop on Programming models for SIMD/Vector processing, pp. 65-70, Feb. 16, 2014, ACM New York, N.Y., USA ©2014, http://dl.acm.org/citation.cfm?id=2568070; and
(2) various aspects of the present invention may have been disclosed by an inventor or a joint inventor in the product Algo One V5.0, made publically available on Dec. 6, 2013. The following documentation is provided in support:
   (i) IBM Software support lifecycle, Algo One V5.0.0, http://www-01.ibm.com/software/support/lifecycleapp/PLCDetail.wss?synkey=D840645J54788H24 &from=spf; and
   (ii) IBM Algo One V5.0 delivers a comprehensive solution for building risk management systems, http://www-01.ibm.com/common/ssi/cgibin/ssialias?subtype=ca&infotype=an&appname=iSource&supplier=897&letternum=EN US213-530.

### BACKGROUND OF THE INVENTION

The present invention relates generally to the field of data processing, and more particularly to non-recursive reduction methods.

Finite-precision floating-point summation is a very common underlying operation for many statistical computations used in financial risk analysis. Therefore, it is critically important to have a summation algorithm that is both fast in speed and produces an accurate result. For example, inside the Mark-to-future aggregation engine, Kahan summation is used in the Credit Value Adjustment (CVA) computation to boost summation accuracy, while compromising on speed. Speed is reduced by introducing additional arithmetic operation into the Kahan summation algorithm that achieves high accuracy. As the demand for real-time CVA and aggregation rises, an approach that achieves high accuracy summation results without severely affecting performance would be an advancement in the art.

### SUMMARY

As disclosed herein a method, executed by a computer, for conducting non-recursive cascading reduction includes receiving a collection of floating point values, using a binary representation of an index corresponding to a value being processed to determine a reduction depth for elements on a stack to be accumulated, and according to the reduction depth, iteratively conducting a reduction operation on the current value and one or more values on the stack. In addition to accumulation, the reduction operation may include transforming the value with a corresponding function. The method may also include using a SIMD processing environment to further increase the performance of the method. The method provides results with both high performance and accuracy. A computer system, and computer program product corresponding to the method are also disclosed herein.

### BRIEF DESCRIPTION OF THE SEVERAL VIEWS OF THE DRAWINGS

FIG. 1 is a functional block diagram of one embodiment of a data processing environment in which at least some of the embodiments disclosed herein may be deployed, in accordance with an embodiment of the present invention;

FIG. 2 is a flowchart depicting one embodiment of a non-recursive cascading reduction method, in accordance with an embodiment of the present invention;

FIG. 3a is a flowchart depicting one embodiment of a reduction operation using a binary index, in accordance with an embodiment of the present invention;

FIG. 3b is a text diagram illustrating a specific example of non-recursive cascading reduction;

FIG. 4 is a functional block diagram of one embodiment of a SIMD processing environment which may be utilized by at least some of the embodiments disclosed herein, in accordance with an embodiment of the present invention; and

FIG. 5 is a block diagram depicting various components of one embodiment of a computer suitable for executing the methods disclosed herein, in accordance with an embodiment of the present invention.

### DETAILED DESCRIPTION

Summation of a collection of numbers is also known as reduction. Applicants have observed the need for a floating point reduction method that is both fast and accurate. Currently available floating point reduction algorithms involve tradeoffs between performance and accuracy when accumulating large collections of floating point values. For example, operations involving recursion incur extensive overhead, resulting in poor performance, while naively accumulating the sum in sequence may result in a substantial round-off error. The embodiments disclosed herein were developed in response to the observations of the Applicants and provide a reduction method that is both fast and maintains accuracy.

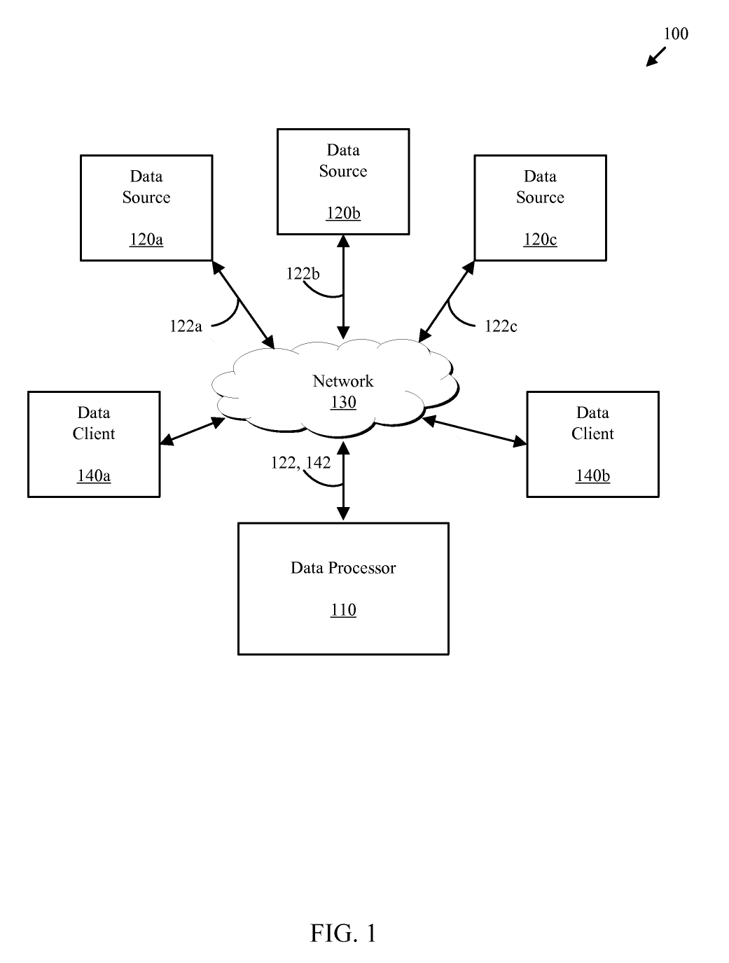

FIG. 1 is a functional block diagram of one embodiment of a data processing environment 100. As depicted, the data processing environment 100 includes a data processor 110, one or more data sources 120 (e.g., data sources 120a, 120b, and 120c), a network 130, and one or more data clients 140 (e.g., data clients 140a and 140b). The data processing environment 100 is one example of an environment in which at least some of the embodiments disclosed herein may be deployed.

The data processor 110 processes a collection of values provided by, or retrieved from, the data sources 120. The data sources 120 may be accessible to the data processor 110 via the network 130. One or more data clients 140 may also be connected to the data processor 110 via the network 130. In some embodiments, the data sources 120 are also data clients 140.

Data 122 provided by the data sources 120 may be a collection of values to be processed by a shift and reduce method or other data processing operation. The collection of values may include, but is not limited to, programming constructs such as a list, an array, a vector, or a matrix. In one embodiment, the collection of values that comprise the data 122 will be an array of values of known data type and length. The data processor 110 is configured to process the data 122 and provide reduced data 142.

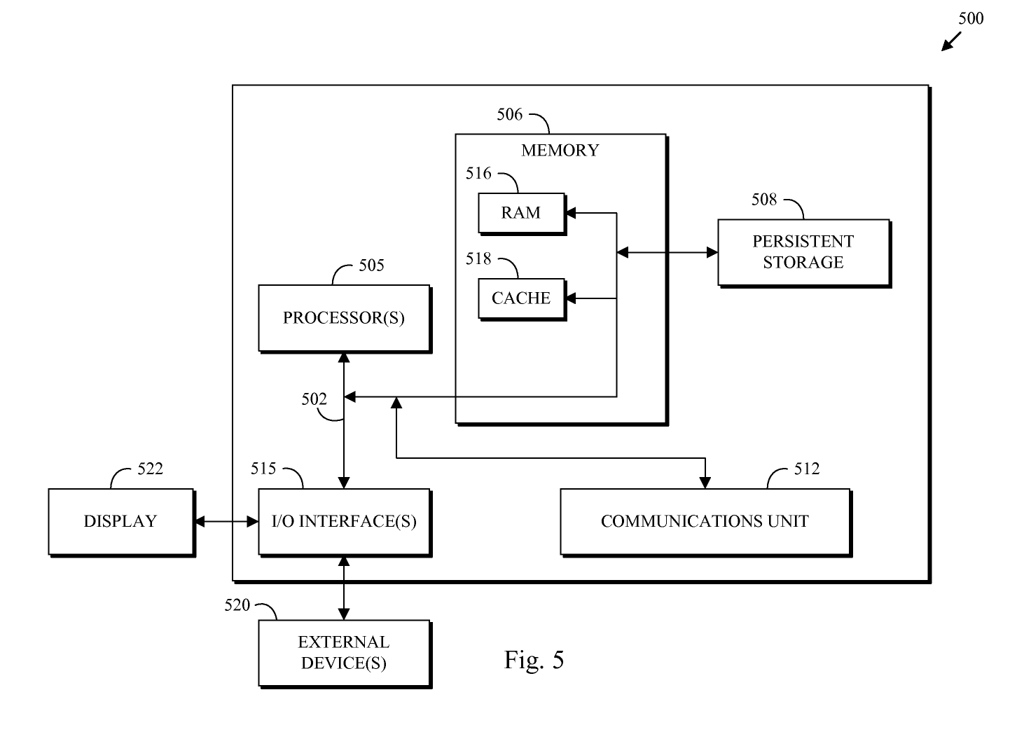

It should be noted that the data processor 110 may include internal and external hardware components, as depicted and described in further detail with respect to FIG. 5. Furthermore, the network 130 can be any combination of connections and protocols that will support communications between the data processor 110, the data sources 120, and the data clients (i.e., data consumers) 140. For example, the network 130 can be a local area network (LAN), a wide area network (WAN) such as the Internet, or a combination of the two, and can include wired, wireless, or fiber optic connections.

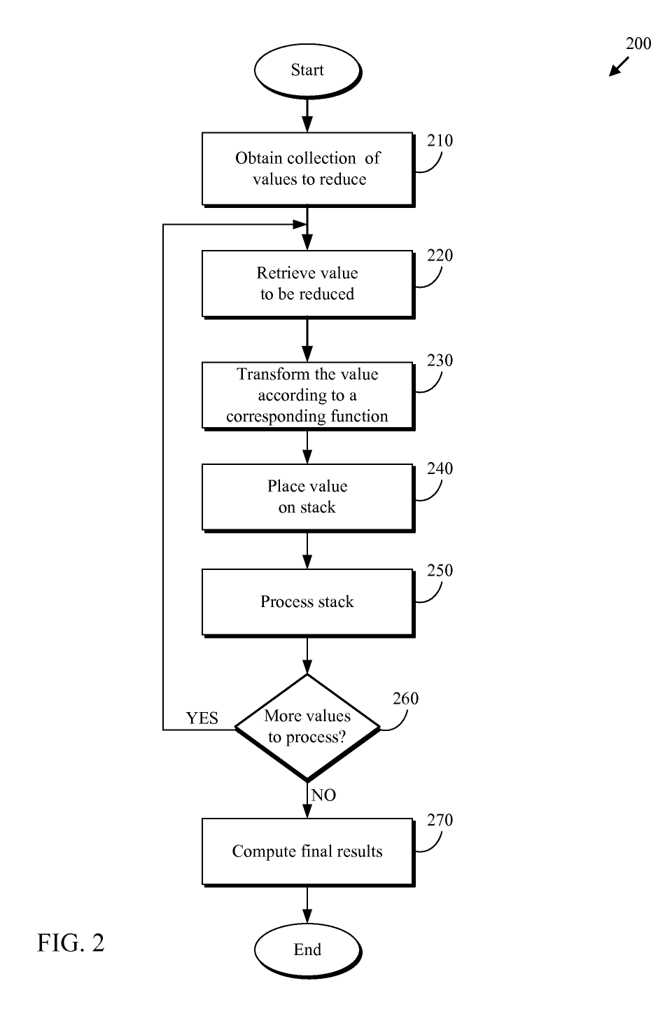

FIG. 2 is a flowchart depicting one embodiment of a non-recursive cascading reduction method 200. As depicted, the non-recursive cascading reduction method 200 includes obtaining (210) a collection of values to be reduced, retrieving (220) a value to be reduced, transforming (230) the value according to a corresponding function, placing (240) the value on a stack, processing (250) the stack, determining (260) whether there are more values to process, and computing (270) final results. The non-recursive cascading reduction method 200 may be used on various systems, including those that are SIMD capable, to efficiently and accurately reduce large collections of values.

Obtaining (210) a collection of values to reduce may include receiving a collection of values from one or more sources. The collection of values could be from a shared memory location, a local storage device, or from an external source that provides the collection of values over an intranet or internetwork. The collection of values may be divided into equal parts in preparation for processing by a SIMD capable apparatus.

Retrieving (220) a value to be reduced may include obtaining one or more values from the (210) collection of values. In one embodiment, a pointer is used to mark the position of the current value in a list. In another embodiment, the values are passed in an array, and an index is used to indicate the current value.

Transforming (230) the value according to a corresponding function may include specialized processing of the value. In one embodiment, the transformation may include applying a function to transform each input, such as is required of a map and reduce algorithm. In another embodiment, the transformation may include producing a dot product of two vectors (X and Y), where the function performed is X[i]*Y[i]. Those of skill in the art will understand that the transforming operation may be optional and need not be executed in every embodiment.

Placing (240) the value on a stack may include pushing the value or the transformed value on a local instance of the stack. In one embodiment, the stack resides in L1 cache resulting in minimal load latency and overhead. Those of skill in the art will appreciate that pushing the value on the stack may also be referred to as shifting.

Processing (250) the stack may include determining if a value exists on the stack to be processed. In one embodiment the stack contains at least one value to be processed if a stack index corresponds to location other than the bottom of the stack. In another embodiment, an ‘isempty’ method corresponding to the stack is called to determine if the stack contains a value to be processed. One or more values may be popped from the stack and a corresponding operation or algorithm performed on the one or more values, producing a new value. The new value may be pushed on the stack to be available for subsequent stack operations.

Determining (260) whether there are more values to process may include verifying if there are more values available in the (210) collection of values by testing a current index corresponding to the collection of values or some other procedure well known to those of skill in the art. If the collection of values contains additional values to be processed, the depicted method 200 iterates to the retrieving operation 220. Otherwise, the method proceeds to the computing operation 270.

Computing (270) final results may include popping all remaining values from the stack. In one embodiment, all values remaining on the stack are popped, and a corresponding operation or algorithm is performed to produce a final result consisting of a single value. In another embodiment, all values produced on a SIMD capable apparatus are merged or accumulated to produce a final result consisting of a single value.

Calling a function or procedure may have overhead associated with each call. The overhead may be attributed to pushing parameters on a call stack and releasing the call stack prior to exiting the function call. Recursion may have many function calls and therefore incur excessive overhead. Using iterative processing and avoiding recursion can eliminate overhead caused by recursion.

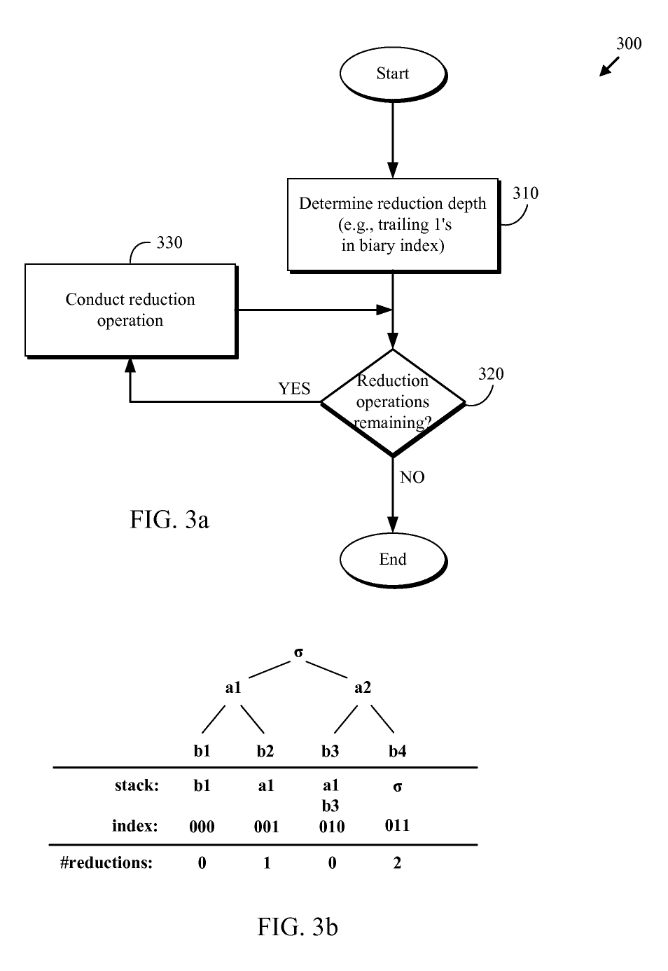

FIG. 3a is a flowchart depicting one embodiment of a reduction method 300. As depicted, the reduction method 300 includes determining (310) a reduction depth, determining if (320) reduction operations remain, and conducting (330) a reduction operation. The reduction method 300 may be used to efficiently cascade through and process values on a stack.

Determining (310) a reduction depth may include determining how many items on a stack should be processed. In one embodiment, the number of trailing ones present in a binary representation of an index corresponding to the current value being processed indicates the reduction depth. The reduction depth corresponds to the number of values to be processed on the stack.

In another embodiment, 2̂m numbers are retrieved from the collection of values—where 2̂m=number of SIMD lanes being utilized. The reduction depth may be determined by dividing the binary representation of an index corresponding to the current value by 2̂m and looking at the trailing ones of the resulting value. Dividing the index by 2̂m effectively drops or ignores the number of bits corresponding to the number of SIMD slices. Alternatively, the lower m bits may be ignored in determining the reduction depth.

Determining if (320) reduction operations remain may include verifying if the number of reductions processed directly correspond to the reduction depth. Those of skill in the art may notice that, as used herein, reduction includes popping a value from the stack and performing an operation such as summing. If there are reductions remaining to be processed, the depicted method 300 proceeds to conducting a reduction operation 330. Otherwise, no reduction operations are required, and the method terminates.

Conducting (330) a reduction operation may include popping one or more values from the stack and performing a corresponding operation or algorithm. In one embodiment, the top two values on the stack are popped, accumulated to produce a new value, and the new value is pushed on the stack. In another embodiment, the top value on the stack is popped and added to an accumulation. If there are no additional reductions required, the accumulation is pushed on the stack.

FIG. 3b is a text diagram illustrating a specific example of non-recursive cascading reduction. The diagram depicts the stack, binary index, and reduction depth as it may appear during the operations described in FIG. 2 and FIG. 3a. The text diagram illustrates accumulating four values (i.e., b1, b2, b3, and b4). The reduction depth illustrated corresponds to the number of trailing ones in the binary representation of the current index. Also illustrated is the contents of the stack at the completion of each iteration.

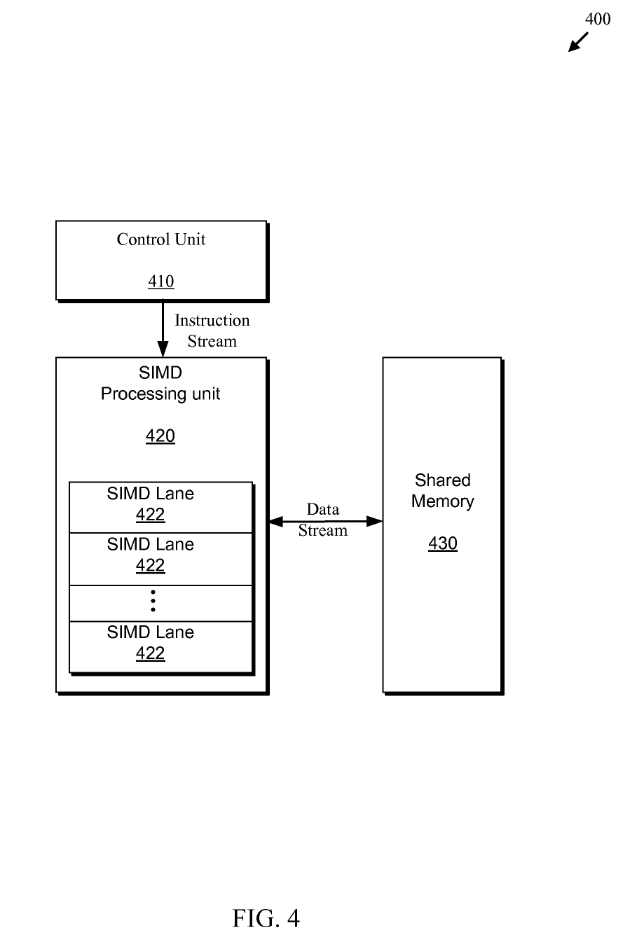

FIG. 4 is a functional block diagram of one embodiment of a single instruction, multiple data (SIMD) processing environment 400. As depicted, the SIMD processing environment 400 includes a control unit 410, a SIMD processing unit 420, two or more SIMD lanes 422, and a shared memory 430. The SIMD processing environment 400 is capable of concurrent (i.e., parallel) processing, allowing data to be evenly distributed between the two or more processing units and a single SIMD instruction to be executed against the data on each processing unit.

The control unit 410 is a single instruction processor responsible for fetching and interpreting computer instructions corresponding to values being processed. In one embodiment, the control unit 410 encounters an arithmetic or other data processing instruction and broadcasts the instruction to the SIMD processing unit 420. The SIMD processing unit 420 may be partitioned into two or more SIMD lanes 422. Multiple SIMD lanes may perform the same arithmetic or other data processing operation, and thereby process multiple values in parallel. In a typical SIMD machine, only one control unit 410 fetches and processes instructions, allowing more logic to be dedicated to the SIMD processing unit (420) and SIMD lanes (422). Dividing large collections of floating point values into partitions and processing them in parallel using SIMD technology typically increases performance and efficiency.

FIG. 5 is a block diagram depicting one example of a computing apparatus (i.e., computer) suitable for executing the methods disclosed herein. The computer 500 may be one embodiment of the data processor 110 depicted in FIG. 1. It should be appreciated that FIG. 5 provides only an illustration of one implementation and does not imply any limitations with regard to the environments in which different embodiments may be implemented. Many modifications to the depicted environment may be made.

As depicted, the computer 500 includes communications fabric 502, which provides communications between computer processor(s) 505, memory 506, persistent storage 508, communications unit 512, and input/output (I/O) interface(s) 515. Communications fabric 502 can be implemented with any architecture designed for passing data and/or control information between processors (such as microprocessors, communications and network processors, etc.), system memory, peripheral devices, and any other hardware components within a system. For example, communications fabric 502 can be implemented with one or more buses.

Memory 506 and persistent storage 508 are computer readable storage media. In this embodiment, memory 506 includes random access memory (RAM) 516 and cache memory 518. In general, memory 506 can include any suitable volatile or non-volatile computer readable storage media.

One or more programs may be stored in persistent storage 508 for execution by one or more of the respective computer processors 505 via one or more memories of memory 506. The persistent storage 508 may be a magnetic hard disk drive, a solid state hard drive, a semiconductor storage device, read-only memory (ROM), erasable programmable read-only memory (EPROM), flash memory, or any other computer readable storage media that is capable of storing program instructions or digital information.

The media used by persistent storage 508 may also be removable. For example, a removable hard drive may be used for persistent storage 508. Other examples include optical and magnetic disks, thumb drives, and smart cards that are inserted into a drive for transfer onto another computer readable storage medium that is also part of persistent storage 508.

Communications unit 512, in these examples, provides for communications with other data processing systems or devices. In these examples, communications unit 512 includes one or more network interface cards. Communications unit 512 may provide communications through the use of either or both physical and wireless communications links.

I/O interface(s) 515 allows for input and output of data with other devices that may be connected to computer 500. For example, I/O interface 515 may provide a connection to external devices 520 such as a keyboard, keypad, a touch screen, and/or some other suitable input device. External devices 520 can also include portable computer readable storage media such as, for example, thumb drives, portable optical or magnetic disks, and memory cards.

Software and data used to practice embodiments of the present invention can be stored on such portable computer readable storage media and can be loaded onto persistent storage 508 via I/O interface(s) 515. I/O interface(s) 515 also connect to a display 522. Display 522 provides a mechanism to display data to a user and may be, for example, a computer monitor.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The embodiments disclosed herein include a system, a method, and/or a computer program product. The computer program product may include a computer readable storage medium (or media) having computer readable program instructions thereon for causing a processor to carry out the methods disclosed herein.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowcharts and block diagrams in the figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

1-9. (canceled)

10. A computer program product for conducting non-recursive cascading reduction, the computer program product comprising:
one or more computer readable storage media and program instructions stored on the one or more computer readable storage media, the program instructions comprising instructions to:
retrieve a value corresponding to a current binary index;
determine a reduction depth corresponding to the current binary index; and
iteratively conduct a reduction operation on the value and one or more values on a stack according to the reduction depth.

11. The computer program product of claim 10, wherein the instructions to iteratively conduct the reduction operation are conducted without recursion.

12. The computer program product of claim 10, wherein the instructions to determine the reduction depth include instructions to determine a number of number of trailing ones within the current binary index.

13. The computer program product of claim 10, wherein the instructions to conduct the reduction operation include SIMD instructions.

14. The computer program product of claim 10, wherein the instructions to conduct the reduction operation include instructions to transform the value with a corresponding function.

15. The computer program product of claim 10, wherein the instructions comprise instructions to push the value onto a stack.

16. A computer system for conducting non-recursive cascading reduction, the computer system comprising:
one or more computer processors;
one or more computer readable storage media;
program instructions stored on the computer readable storage media for execution by at least one of the computer processors, the program instructions comprising instructions to:
retrieve a value corresponding to a current binary index;
determine a reduction depth corresponding to the current binary index; and
iteratively conduct a reduction operation on the value and one or more values on a stack according to the reduction depth.

17. The computer system of claim 16, wherein the instructions to iteratively conduct the reduction operation are conducted without recursion.

18. The computer system of claim 16, wherein the instructions to determine the reduction depth include instructions to determine a number of number of trailing ones within the current binary index.

19. The computer system of claim 16, wherein the instructions to conduct the reduction operation include instructions SIMD instructions.

20. The computer system of claim 16, wherein the instructions to conduct the reduction operation include instructions to transform the value with a corresponding function.
